(19) United States
(12) Patent Application Publication
(10) Pub. No.: US 2008/0012125 A1
(43) Pub. Date: Jan. 17, 2008

(54) Light Emitting Diode Package

(76) Inventor: WON JIN SON, Gwangsan-gu (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/778,115

(22) Filed: Jul. 16, 2007

(30) Foreign Application Priority Data
Jul. 14, 2006 (KR) 10-2006-0066136

(51) Int. Cl. H01L 23/34; H01L 33/00

(52) U.S. Cl. 257/724; 257/99; 257/355

(57) ABSTRACT

Provided is a light emitting diode package. The light emitting diode package includes a base, a light emitting diode mounted in the base, and a driving chip mounted in the base to drive the light emitting diode.

### CROSS-REFERENCE TO RELATED APPLICATION

The present application claims the benefit under 35 U.S.C. § 119 of Korean Patent Application No. 10-2006-0066136, filed Jul. 14, 2006, which is hereby incorporated by reference in its entirety.

### BACKGROUND

A light emitting diode package generally includes a first conduction type semiconductor layer, an active layer, and a second conduction type semiconductor layer, which emits light when power is applied.

The light emitting diode is used for a variety of applications such as in machines and electrical and electronic devices such as display devices, mobile communication terminals, automobiles, and lighting apparatuses.

### BRIEF SUMMARY

Embodiments of the present invention provide a light emitting diode package.

Further embodiments provide a light emitting diode package in which a light emitting diode and a driving chip are mounted together.

According to some embodiments a light emitting diode package is provided that can be manufactured in a small size.

A light emitting diode package according to embodiments of the present invention can maintain stable operation.

In one embodiment, a light emitting diode package can comprise: a base; a light emitting diode mounted in the base; and a driving chip mounted in the base to drive the light emitting diode.

In another embodiment, a light emitting diode package can comprise: a base; a light emitting diode mounted in a groove portion of the base; and a driving chip mounted inside the base to drive the light emitting diode.

The details of one or more embodiments are set forth in the accompanying drawings and the description below. Other features will be apparent from the description and drawings, and from the claims.

### BRIEF DESCRIPTION OF THE DRAWINGS

FIG. 1 is a plan view of a light emitting diode package according to an embodiment.

FIG. 2 is a cross-sectional view taken along line A-A′ of FIG. 1.

FIG. 3 is a circuit diagram of a light emitting diode package according to an embodiment.

FIG. 4 is a perspective view of a light emitting diode package according to an embodiment.

### DETAILED DESCRIPTION

Hereinafter, a light emitting diode package according to embodiments of the present invention will be described in detail with reference to the accompanying drawings.

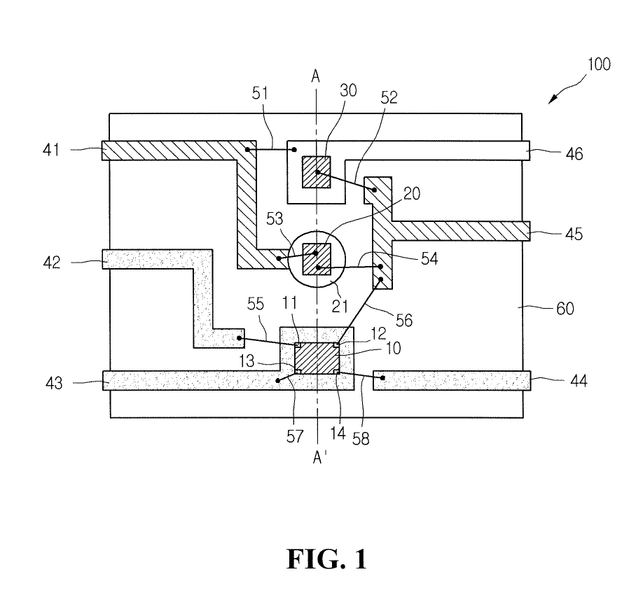

Referring to FIGS. 1 to 4, a light emitting diode package 100 can include a light emitting diode 20, a driving chip 10, and an electrostatic discharge (ESD) protecting device 30 mounted in a base 60.

Referring to FIG. 1, for electrical connection of the light emitting diode 20, the driving chip 10, and the ESD protecting device 30, first, second, third, fourth, fifth, and sixth lead frames 41, 42, 43, 44, 45, and 46, and first, second, third, fourth, fifth, sixth, seventh, and eighth wires 51, 52, 53, 54, 55, 56, 57, and 58 can be installed.

In an embodiment, the wires can be replaced by electrical connection members realized in a pattern line shape such as a strip line.

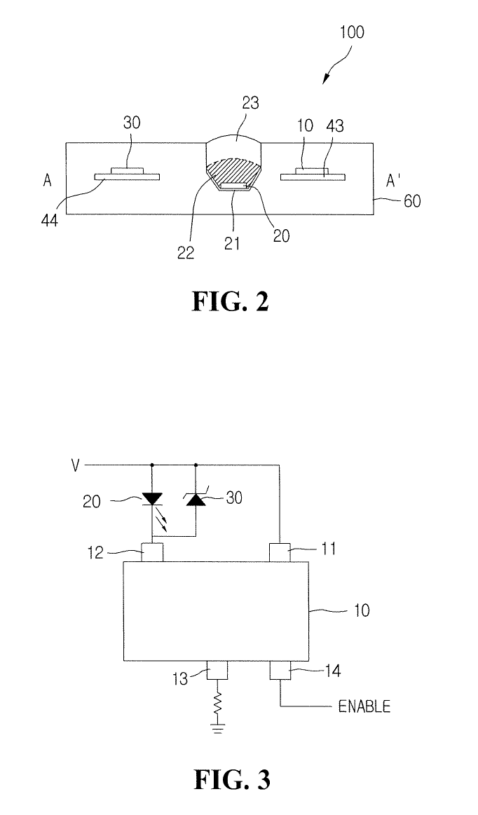

A reflective layer 21 for increasing light efficiency can be formed on the lateral sides and lower side of the light emitting diode 20 as shown in FIG. 2. A molding member 22 for protecting the light emitting diode 20, and a lens unit 23 for changing an orientation angle of light emitted from the light emitting diode 20 or increasing light efficiency can be formed on the light emitting diode 20.

In some embodiments, the molding member 22 can include fluorescent materials. For example, blue light emitted from the light emitting diode 20 can be changed into white light by the fluorescent materials.

The lens unit 23 can include a lens formed in a convex, concave, or Fresnel (flat plate) shape.

Though only one light emitting diode is installed in the drawing for convenience in description, a plurality of light emitting diodes 20 can be installed in the base 60.

The ESD protecting device 30 is designed for protecting the light emitting diode 20 from electrostatic discharge. Examples of the ESD protecting device 30 can include a diode, a zener diode, and a varistor. In one embodiment a zener diode is used as the ESD protecting device 30.

The driving chip 10 controls the operation of the light emitting diode 20, and is electrically connected to the ESD protecting device 30 to protect the light emitting diode 20 from the ESD.

The base 60 supports the driving chip 10, the light emitting diode 20, the ESD protecting device 30, the lead frames (41, 42, 43, 44, 45, and 46), and the wires (51, 52, 53, 54, 55, 56, 57, and 58).

Also, according to certain embodiments, the base is formed of an epoxy resin, a silicon resin, or a ceramic material to effectively discharge heat from the driving chip 10, the light emitting diode 20, and the ESD protecting device 30 to the outside.

The base 60 can be formed through injection molding with the light emitting diode 20, the driving chip 10, the ESD protecting device 30, the lead frames (41, 42, 43, 44, 45, and 46), and the wires (51, 52, 53, 54, 55, 56, 57, and 58) disposed in a mold.

Though not shown in the drawing, a heat transfer material can be coated or a heatsink plate can be attached on a lower surface of the base 60 to enhance heatsink efficiency.

The lead frames 41, 42, 43, 44, 45, and 46 can be formed of metal to provide power or a signal to the light emitting diode 20, the driving chip 10, and the ESD protecting device 30, and allow heat generated from the light emitting diode 20, the driving chip 10, and the ESD protecting device 30 to be swiftly transferred to the outside.

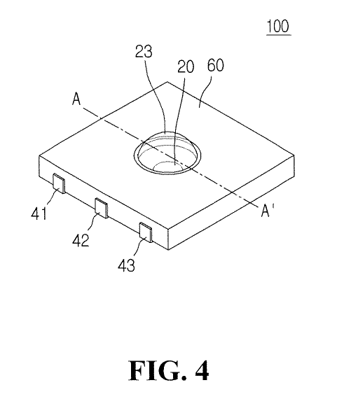

That is, referring to FIG. 4, the lead frames (41, 42, 43, 44, 45, and 46) protrude to the lateral sides of the base 60 and are exposed to the outside. Therefore, power or a signal can be provided via the lead frames (41, 42, 43, 44, 45, and 46), and heat can be effectively discharged.

Referring to FIG. 1, the first lead frame 41 can be connected to the ESD protecting device 30 via the first wire 51, and connected to the light emitting diode 20 via the third wire 53. The first lead frame 41 provides a driving voltage to the ESD protecting device 30 and the light emitting diode 20.

The sixth lead frame 46 can be connected to the first wire 51, and connected to a bottom electrode of the ESD protecting device 30. Therefore, the first lead frame 41 is electrically connected to the sixth lead frame 46 and the ESD protecting device 30 via the first wire 51.

The fifth lead frame 45 can be connected to the ESD protecting device 30 via the second wire 52, and connected to the light emitting diode 20 via the fourth wire 54, and connected to a second electrode 12 of the driving chip 10 via the sixth wire 56.

The sixth lead frame 46 and the fifth lead frame 45 can additionally provide a path for testing whether the light emitting diode package normally operates.

The second lead frame 42 can be connected to a first electrode 11 of the driving chip 10 via the fifth wire 55.

The second lead frame 42 applies a driving voltage to the driving chip 10.

Referring to FIG. 3, the same voltage is used to apply voltage to the first electrode 11 and a second electrode 12 of the driving chip 10.

That is, in an embodiment, the same voltage is applied to the light emitting diode 20 and the driving chip 10. Therefore, voltages applied to the first and second lead frames 41 and 42 are set to the same voltage.

The third lead frame 43 can be connected to a third electrode 13 of the driving chip 10 via the seventh wire 57.

The third lead frame 43 varies internal resistance of the driving chip 10 to control the operation of the light emitting diode 20, or provides a path through which an analog or digital signal controlling the driving chip 10 can be applied from an external apparatus.

The fourth lead frame 44 can be connected to the fourth electrode 14 of the driving chip 10 via the eighth wire 58.

The fourth lead frame 44 provides a path through which the operation of the light emitting diode 20 can be turned on/off by providing an enable signal to the driving chip 10.

In the light emitting diode package according to an embodiment, the light emitting diode 20 and the driving chip 10 are mounted in one base 60 and manufactured in a package type.

Also, the ESD protecting device 30 can be included in the light emitting diode package. The light emitting diode 20 and the ESD protecting device 30 can be connected in parallel.

Here, the driving chip 10, the light emitting diode 20, and the ESD protecting device 30 are electrically connected.

The driving chip 10 is designed to control the operation of the light emitting diode 20. A driving chip 10 suitable for the kind, the quantity, and the driving method of the mounted light emitting diode 20 can be selected and mounted in the base 60.

In further embodiments, the driving chip 10 can be designed to receive a suitable program that can control the operation of the light emitting diode 20 via the third lead frame 43 connected to the driving chip 10, or the driving chip 10 can be designed to be suitably controlled by an external apparatus. The driving chip 10 can be mounted in the base 60.

Therefore, since the driving chip 10 suitable for the mounted light emitting diode 20 is mounted in the light emitting diode package, limitation in a circuit design related to driving of the light emitting diode 20 is not generated to a manufacturer applying the light emitting diode 20 to a product.

Also, since the driving chip 10 suitable for the light emitting diode 20 is mounted together with the light emitting diode 20, a malfunction due to selection of an erroneous driving chip 10 can be avoided.

Also, since the light emitting diode package incorporates the light emitting diode 20 and the driving chip 10 together, the light emitting package according to an embodiment can be manufactured in a small size compared to the case where the light emitting diode 20 and the driving chip 10 are separately designed and mounted in a circuit board.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A light emitting diode package comprising:
a base;
a light emitting diode mounted in the base; and
a driving chip mounted in the base to drive the light emitting diode.

2. The light emitting diode package according to claim 1, wherein the base is formed of a resin or a ceramic material.

3. The light emitting diode package according to claim 1, wherein the driving chip is completely surrounded inside the base.

4. The light emitting diode package according to claim 1, further comprising an electrostatic discharge protecting device mounted in the base and connected to the light emitting diode.

5. The light emitting diode package according to claim 4, wherein the light emitting diode and the electrostatic discharge protecting device are connected in parallel.

6. The light emitting diode package according to claim 4, wherein the electrostatic discharge protecting device comprises at least one selected from the group consisting of a diode, a zener diode, and a varistor.

7. The light emitting diode package according to claim 1, further comprising a lead frame for providing power or a signal to the driving chip and the light emitting diode.

8. The light emitting diode package according to claim 7, wherein the lead frame is located inside the base and protrudes to a lateral side of the base.

9. The light emitting diode package according to claim 7, wherein the driving chip and the light emitting diode are connected to the lead frame using an electrical connecting member.

10. The light emitting diode package according to claim 1, wherein the light emitting diode is located in a recessed portion of the base.

11. The light emitting diode package according to claim 10, further comprising a reflective layer for enhancing light efficiency formed on lateral sides and a lower side of the light emitting diode, and
a molding member and a lens unit formed on an upper side of the light emitting diode.

12. The light emitting diode package according to claim 11, wherein the lens unit comprises at least one lens selected from the group consisting of a convex lens, a concave lens, and a Fresnel lens.

13. The light emitting diode package according to claim 1, wherein a plurality of light emitting diodes are provided in the base.

14. The light emitting diode package according to claim 1, wherein the light emitting diode is electrically connected to a first lead frame and fifth lead frame, and
a first electrode, third electrode, and fourth electrode of the driving chip are electrically connected to a second lead frame, third lead frame, and fourth lead frame, respectively, and a second electrode of the driving chip is electrically connected to the fifth lead frame.

15. The light emitting diode package according to claim 14, further comprising an electrostatic discharge protecting device mounted in the base and connected to the light emitting diode, wherein the electrostatic discharge protecting device is electrically connected to the first lead frame, the fifth lead frame, and a sixth lead frame.

16. A light emitting diode package comprising:
a base;
a light emitting diode mounted in a groove portion of the base; and
a driving chip mounted inside the base to drive the light emitting diode.

17. The light emitting diode package according to claim 16, further comprising a lead frame electrically connected to the light emitting diode and the driving chip, wherein the lead frame has a portion located inside the base and another portion exposed at an outside of the base.

18. The light emitting diode package according to claim 16, further comprising an electrostatic discharge protecting device mounted in the base and connected to the light emitting diode in parallel.
